(19) United States
(12) Patent Application Publication
(10) Pub. No.: US 2025/0023546 A1
(43) Pub. Date: Jan. 16, 2025

(54) ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Akihiro IYAMA, Nagaokakyo-shi (JP)

(21) Appl. No.: 18/884,546

(22) Filed: Sep. 13, 2024

Related U.S. Application Data
(63) Continuation of application No. PCT/JP2023/012261, filed on Mar. 27, 2023.
(60) Provisional application No. 63/324,362, filed on Mar. 28, 2022.

(51) Int. Cl. H03H 9/145; H03H 9/02; H03H 9/05

(52) U.S. Cl. CPC H03H 9/14541; H03H 9/02031; H03H 9/02157; H03H 9/0504

(57) ABSTRACT

An acoustic wave device includes a support including a support substrate, a piezoelectric layer on the support, an IDT electrode on the piezoelectric layer and including a pair of busbars and electrode fingers, and mass addition films on the electrode fingers. An acoustic reflection portion overlaps at least a portion of the IDT electrode. d/p is about 0.5 or smaller. A region in which adjacent electrode fingers overlap each other is a cross region including a central region, and first and second edge regions. At least a portion of the mass addition films overlap the central region. A width of at least one of the mass addition films is different from a width of other mass addition films.

### CROSS REFERENCE TO RELATED APPLICATIONS

This application claims the benefit of priority to Provisional Application No. 63/324,362 filed on Mar. 28, 2022 and is a Continuation Application of PCT Application No. PCT/JP2023/012261 filed on Mar. 27, 2023. The entire contents of each application are hereby incorporated herein by reference.

### BACKGROUND OF THE INVENTION

### 1. Field of the Invention

The present invention relates to acoustic wave devices.

### 2. Description of the Related Art

In the related art, an acoustic wave device is widely used for a filter or the like of a mobile phone. In recent years, as described in U.S. Pat. No. 10,491,192, an acoustic wave device using a bulk wave in a thickness shear mode has been proposed. In the acoustic wave device, a piezoelectric layer is provided on a support body. A pair of electrodes are provided on the piezoelectric layer. The pair of electrodes face each other on the piezoelectric layer, and are connected to mutually different potentials. An alternating current voltage is applied between the electrodes to excite the bulk wave in the thickness shear mode.

In the acoustic wave device described in U.S. Pat. No. 10,491,192, a plate wave mode and a harmonic wave thereof become powerful unnecessary waves. Therefore, when the acoustic wave device is used in a filter device, there is a possibility that filter characteristics deteriorate.

### SUMMARY OF THE INVENTION

Example embodiments of the present invention provide acoustic wave devices each of which reduces or prevents unnecessary waves.

An acoustic wave device according to an example embodiment of the present invention includes a support including a support substrate, a piezoelectric layer on the support, an IDT electrode on the piezoelectric layer and including a pair of busbars facing each other and a plurality of electrode fingers, and a plurality of mass addition films on the plurality of electrode fingers. In a plan view along a lamination direction of the support and the piezoelectric layer, an acoustic reflection portion is provided at a position overlapping with at least a portion of the IDT electrode in the support. When a thickness of the piezoelectric layer is defined as d and a center-to-center distance between the adjacent electrode fingers is defined as p, d/p is about 0.5 or smaller. When viewed in an electrode finger orthogonal direction orthogonal or substantially orthogonal to an electrode finger extending direction in which the plurality of electrode fingers extend, a region in which adjacent electrode fingers overlap each other is a cross region. The cross region includes a central region, and a first edge region and a second edge region facing each other across the central region in the electrode finger extending direction. At least a portion of the plurality of mass addition films each overlaps the central region in a plan view. When a dimension of the plurality of mass addition films along the electrode finger orthogonal direction is defined as a width of the plurality of mass addition films, a width of at least one of the plurality of mass addition films is different from a width of others of the plurality of mass addition films.

According to example embodiments of the present invention, it is possible to provide acoustic wave devices each of which reduces or prevents unnecessary waves.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a view showing admittance frequency characteristics in the first example embodiment and a comparative example of the present invention.

FIG. 4 is a view showing the admittance frequency characteristics on a lower band side of a resonant frequency in the first example embodiment and the comparative example of the present invention.

FIG. 5 is a view showing the admittance frequency characteristics on a higher band side of an anti-resonant frequency in the first example embodiment and the comparative example of the present invention.

FIG. 6 is a schematic plan view of an acoustic wave device according to a second example embodiment of the present invention.

FIG. 7 is a schematic plan view of an acoustic wave device according to a third example embodiment of the present invention.

FIG. 8 is a schematic plan view of an acoustic wave device according to a fourth example embodiment of the present invention.

FIG. 9 is a schematic plan view of an acoustic wave device according to a fifth example embodiment of the present invention.

FIG. 10 is a circuit diagram of a filter device according to a sixth example embodiment of the present invention.

FIG. 11A is a schematic perspective view showing an appearance of an acoustic wave device using a bulk wave in a thickness shear mode, and FIG. 11B is a plan view showing an electrode structure on a piezoelectric layer.

FIG. 12 is a cross-sectional view of a portion taken along line A-A in FIG. 11A.

FIG. 13A is a schematic elevational cross-sectional view showing a Lamb wave propagating through a piezoelectric film of the acoustic wave device, and FIG. 13B is a schematic elevational cross-sectional view showing the bulk wave in the thickness shear mode, which propagates through the piezoelectric film in the acoustic wave device.

FIG. 14 is a view showing an amplitude direction of the bulk wave in the thickness shear mode.

FIG. 15 is a view showing resonance characteristics of the acoustic wave device using the bulk wave in the thickness shear mode.

FIG. 16 is a view showing a relationship between d/p and a fractional bandwidth as a resonator when a center-to-center distance of adjacent electrodes is defined as p and a thickness of a piezoelectric layer is defined as d.

FIG. 17 is a plan view of an acoustic wave device using a bulk wave in a thickness shear mode.

FIG. 18 is a view showing resonance characteristics of an acoustic wave device in a reference example in which a spurious wave appears.

FIG. 19 is a view showing a relationship between the fractional bandwidth and a phase rotation amount of impedance of the spurious wave standardized at about 180 degrees as a magnitude of the spurious wave.

FIG. 20 is a view showing a relationship between d/2p and a metallization ratio MR.

FIG. 21 is a view showing a map of the fractional bandwidth with respect to Euler angles (0°, θ, and ψ) of LiNbO₃ when d/p is infinitely close to 0.

FIG. 22 is an elevational cross-sectional view of an acoustic wave device including an acoustic multilayer film.

### DETAILED DESCRIPTION OF THE EXAMPLE EMBODIMENTS

Hereinafter, the present invention will be clearly understood by describing specific example embodiments of the present invention with reference to the drawings.

Each example embodiment described in the present specification is merely an example, and configurations can be partially replaced or combined with each other between different example embodiments.

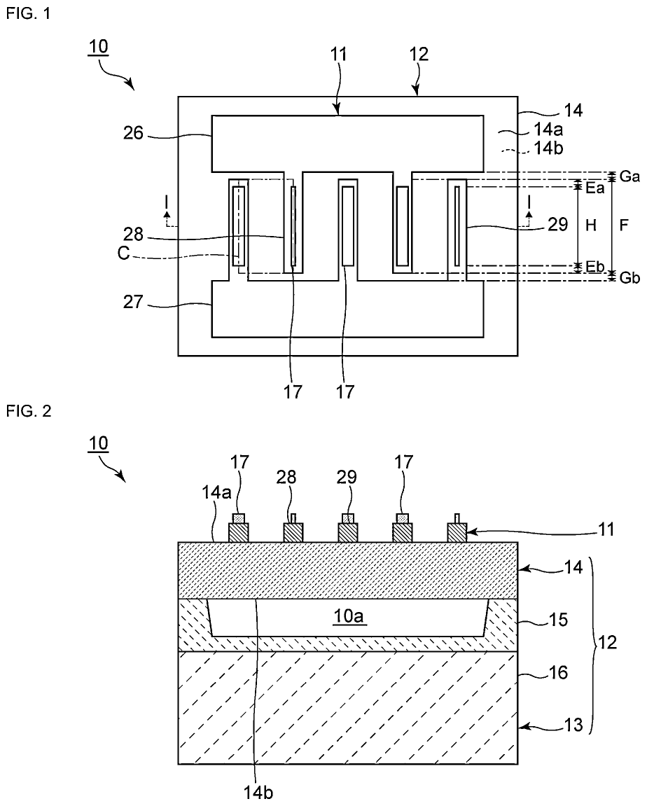

FIG. 1 is a schematic plan view of an acoustic wave device according to a first example embodiment of the present invention. FIG. 2 is a schematic cross-sectional view taken along line I-I in FIG. 1.

As shown in FIG. 1, an acoustic wave device 10 includes a piezoelectric substrate 12 and an IDT electrode 11. As shown in FIG. 2, the piezoelectric substrate 12 includes a support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. The support 13 may include only the support substrate 16.

The piezoelectric layer 14 includes a first main surface 14a and a second main surface 14b. The first main surface 14a and the second main surface 14b face each other. Of the first main surface 14a and the second main surface 14b, the second main surface 14b is located on the support 13 side.

As a material of the support substrate 16, for example, a semiconductor such as silicon, ceramics such as aluminum oxide, or the like can be used. As a material of the insulating layer 15, an appropriate dielectric such as, for example, silicon oxide or tantalum oxide can be used. For example, the piezoelectric layer 14 is a lithium niobate layer such as a LiNbO₃ layer or a lithium tantalate layer such as a LiTaO₃ layer.

As shown in FIG. 2, a recess portion is provided in the insulating layer 15. The piezoelectric layer 14 is provided on the insulating layer 15 to close the recess portion. In this manner, a hollow portion is provided. The hollow portion is a cavity portion 10a. In the present example embodiment, the support 13 and the piezoelectric layer 14 are disposed such that a portion of the support 13 and a portion of the piezoelectric layer 14 face each other across the cavity portion 10a. The recess portion in the support 13 may be provided over the insulating layer 15 and the support substrate 16. Alternatively, the recess portion provided only in the support substrate 16 may be closed by the insulating layer 15. The recess portion may be provided in the piezoelectric layer 14. The cavity portion 10a may be, for example, a through hole provided in the support 13.

The IDT electrode 11 is provided on the first main surface 14a of the piezoelectric layer 14.

In a plan view, at least a portion of the IDT electrode 11 overlaps the cavity portion 10a of the piezoelectric substrate 12. In the present specification, description of “in a plan view” means that an object is viewed along a lamination direction of the support 13 and the piezoelectric layer 14 from a direction corresponding to an upward direction in FIG. 2. In FIG. 2, for example, the piezoelectric layer 14 side is an upper side of the support substrate 16 side and the piezoelectric layer 14 side.

As shown in FIG. 1, the IDT electrode 11 includes a pair of busbars and a plurality of electrode fingers. Specifically, the pair of busbars include a first busbar 26 and a second busbar 27. The first busbar 26 and the second busbar 27 face each other. Specifically, the plurality of electrode fingers include a plurality of first electrode fingers 28 and a plurality of second electrode fingers 29. Each one end of the plurality of first electrode fingers 28 is connected to the first busbar 26. Each one end of the plurality of second electrode fingers 29 is connected to the second busbar 27. The plurality of first electrode fingers 28 and the plurality of second electrode fingers 29 are interdigitated with each other. The IDT electrode 11 may include a single metal film, or may include a laminated metal film.

Hereinafter, the first busbar 26 and the second busbar 27 may be simply referred to as a busbar. The first electrode finger 28 and the second electrode finger 29 may be simply referred to as an electrode finger. Each electrode finger includes a tip portion and a base end portion. The base end portion in the electrode finger is a portion connected to the busbar. When an extending direction of the plurality of electrode fingers is defined as an electrode finger extending direction, the base end portion and the tip portion face each other in the electrode finger extending direction.

Here, a direction orthogonal or substantially orthogonal to the electrode finger extending direction will be referred to as an electrode finger orthogonal direction. When a direction in which adjacent electrode fingers face each other is defined as an electrode finger facing direction, the electrode finger facing direction is parallel or substantially parallel to the electrode finger orthogonal direction. When the IDT electrode 11 is viewed in the electrode finger orthogonal direction, a region in which the adjacent electrode fingers overlap each other is a cross region F. The cross region F is a region of the piezoelectric layer 14 which is defined based on a configuration of the IDT electrode 11.

The cross region F includes a central region H and a pair of edge regions. The pair of edge regions face each other across the central region H in the electrode finger extending direction. Specifically, the pair of edge regions include a first edge region Ea and a second edge region Eb. The first edge region Ea is located on the first busbar 26 side. The second edge region Eb is located on the second busbar 27 side.

A region located between the cross region F and the pair of busbars includes a pair of gap regions. Specifically, the pair of gap regions include a first gap region Ga and a second gap region Gb. The first gap region Ga is located between the first busbar 26 and the first edge region Ea. The second gap region Gb is located between the second busbar 27 and the second edge region Eb. As in the cross region F, each of the gap regions is a region of the piezoelectric layer 14 which is defined based on the configuration of the IDT electrode 11.

The acoustic wave device 10 of the present example embodiment is, for example, an acoustic wave resonator configured such that a bulk wave in a thickness shear mode can be used. More specifically, in the acoustic wave device 10, when the thickness of the piezoelectric layer 14 is defined as d and the center-to-center distance of the adjacent electrode fingers is defined as p, d/p is, for example, about 0.5 or smaller. In this manner, the bulk wave in the thickness shear mode is suitably excited. When viewed in the electrode finger orthogonal direction, a center-to-center region of the adjacent electrode fingers, which is a region in which the adjacent electrode fingers overlap each other, is an excitation region C. That is, the cross region F includes a plurality of excitation regions C. In each excitation region C, the bulk wave in the thickness shear mode is excited.

The cavity portion 10a shown in FIG. 2 is an acoustic reflection portion. The acoustic reflection portion can effectively confine energy of an acoustic wave on the piezoelectric layer 14 side. The acoustic reflection portion may be provided at a position that overlaps at least a portion of the IDT electrode in the support in a plan view. For example, an acoustic reflection film such as an acoustic multilayer film (to be described later) may be provided on a surface of the support, as the acoustic reflection portion.

Referring back to FIG. 1, a plurality of mass addition films 17 are provided on the plurality of electrode fingers. More specifically, in the present example embodiment, the mass addition films 17 are provided one by one on all of the electrode fingers. The mass addition films 17 are continuously provided from a base end portion side to a tip portion side of the electrode finger.

The plurality of mass addition films 17 each overlap only the cross region F in a plan view. In a plan view, the plurality of mass addition films 17 may overlap a region on an outer side of the cross region F in the electrode finger extending direction. At least a portion of the plurality of mass addition films 17 each may overlap the central region H in a plan view.

A width of each of the mass addition films 17 is constant or substantially constant. The width of the mass addition film 17 is a dimension of the mass addition film 17 along the electrode finger orthogonal direction.

The mass addition film 17 is made of silicon oxide, for example. In the present specification, the fact that a certain member is made of a certain material includes a case where a trace amount of impurity is included to the extent that the electric characteristics of the acoustic wave device do not significantly deteriorate. A material of the mass addition film 17 is not limited to the above-described example.

According to characteristics of the present example embodiment, the width of at least one of the mass addition films 17 is different from the width of the other mass addition films 17. In this manner, the unnecessary waves can be reduced or prevented. This advantageous effect will be specifically described below by comparing the present example embodiment and a comparative example with each other.

The comparative example is different from the first example embodiment of the present invention in that the mass addition film is not provided. In the first example embodiment and the comparative example, admittance frequency characteristics are compared.

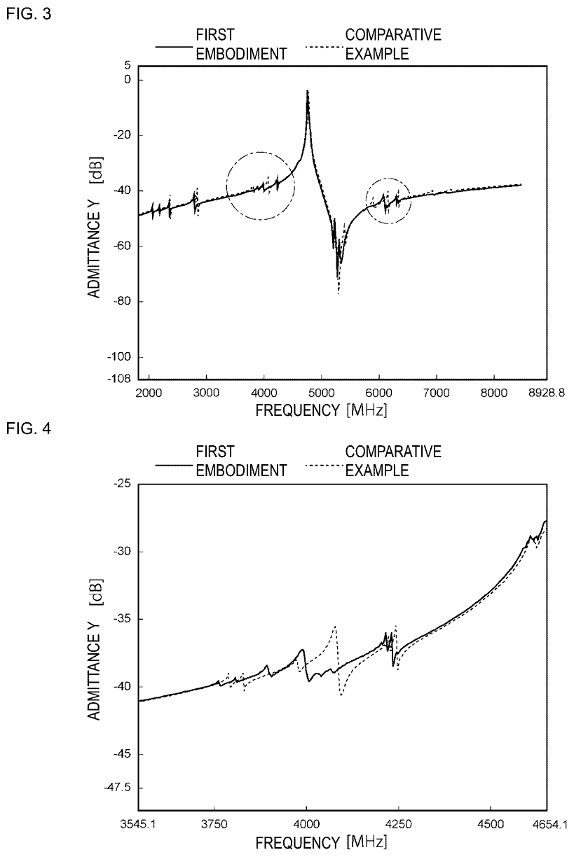

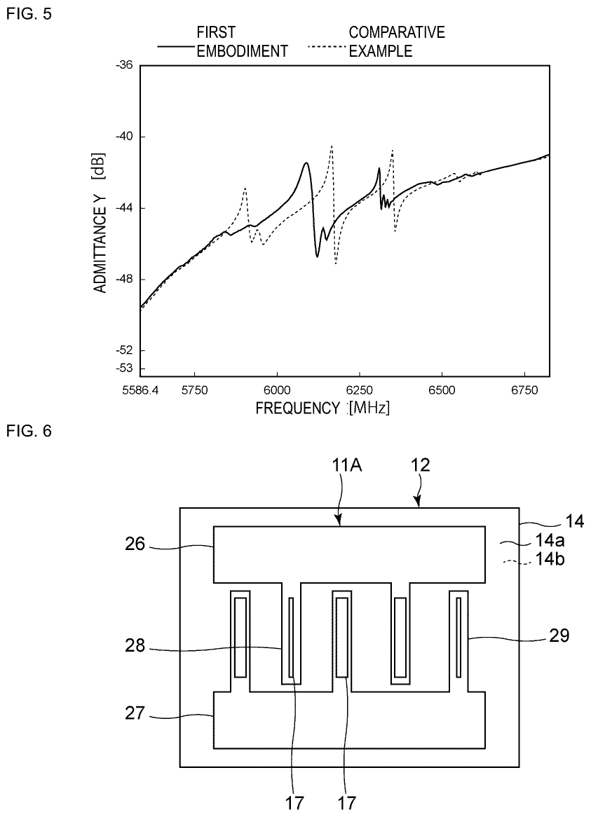

FIG. 3 is a view showing the admittance frequency characteristics in the first example embodiment and the comparative example. FIG. 4 is a view showing the admittance frequency characteristics on a lower band side of a resonant frequency in the first example embodiment and the comparative example. FIG. 5 is a view showing the admittance frequency characteristics on a higher band side of an anti-resonant frequency in the first example embodiment and the comparative example. FIGS. 4 and 5 each show the admittance frequency characteristics in a frequency band in a vicinity of a portion surrounded by a one-dot chain line in FIG. 3.

In the comparative example, unnecessary waves are generated in the vicinity of the frequency band surrounded by the one-dot chain line in FIG. 3. The unnecessary waves are generated in the frequency band on the lower band side of the resonant frequency and in the frequency band on the higher band side of the anti-resonant frequency. The unnecessary waves are caused by plate waves and harmonic waves thereof. As shown in FIGS. 4 and 5, in the first example embodiment, it can be understood that the unnecessary waves are reduced or prevented more than in the comparative example.

As shown in FIG. 1, the reason is that the plurality of mass addition films 17 includes the plurality of mass addition films 17 having mutually different widths. Therefore, it is possible to disperse the frequency at which the unnecessary waves are generated, and it is possible to reduce intensity of the unnecessary waves as a whole.

The mass addition films 17 are not necessarily provided on all of the electrode fingers. The plurality of electrode fingers may include electrode fingers on which the mass addition films 17 are not provided. It is preferable that the mass addition films 17 each are provided on the adjacent electrode fingers, and that the widths of the mass addition films 17 provided on the adjacent electrode fingers are different from each other. It is more preferable that the mass addition films 17 are provided on all of the electrode fingers. In this manner, the unnecessary waves can be effectively reduced or prevented.

It is preferable that the mass addition film 17 overlaps all portions of the cross region F from one end portion to the other end portion in the electrode finger extending direction in a plan view. In this case, the unnecessary waves can be more reliably reduced or prevented.

In the first example embodiment, the IDT electrode 11 is provided on the first main surface 14a of the piezoelectric layer 14. The IDT electrode 11 may be provided on the first main surface 14a or the second main surface 14b of the piezoelectric layer 14. The plurality of mass addition films 17 may be provided on the plurality of electrode fingers in the IDT electrode 11. Even when the IDT electrode 11 is provided on the second main surface 14b, the unnecessary waves can be reduced or prevented as in the first example embodiment.

As described above, the mass addition film 17 is made of silicon oxide, for example. The mass addition film 17 may be made of a dielectric other than silicon oxide. In this case, it is preferable that the density of the mass addition film 17 is higher than density of silicon oxide. Specifically, for example, it is preferable that the mass addition film 17 is made of tantalum oxide or the like. In this manner, the thickness of the mass addition film 17 can be reduced. In this manner, variations in a shape of the mass addition film 17 can be reduced or prevented.

Alternatively, for example, the mass addition film 17 may be made of an appropriate metal. In this case as well, the thickness of the mass addition film 17 can be reduced, and variations in the shape of the mass addition film 17 can be reduced or prevented.

FIG. 1 shows an example in which the plurality of mass addition films 17 have two types of widths, for example. The widths of the plurality of mass addition films 17 may be three types of widths or more.

In the first example embodiment, a line width of each electrode finger of the IDT electrode 11 is constant or substantially constant, the line widths of all of the electrode fingers are the same or substantially the same as each other, and a center-to-center distance p of the adjacent electrode fingers is constant or substantially constant. The line width of the electrode finger is a dimension of the electrode finger along the electrode finger orthogonal direction. In other words, the center-to-center distance p is an electrode finger pitch. A configuration of the IDT electrode 11 is not limited to the above-described example.

Hereinafter, second to fourth example embodiments in which only the configuration of the IDT electrode is different from that of the first example embodiment will be described. In the second to fourth example embodiments, as in the first example embodiment, the width of at least one of the mass addition films is different from the widths of the other mass addition films. In this manner, the unnecessary waves can be reduced or prevented.

FIG. 6 is a schematic plan view of an acoustic wave device according to a second example embodiment of the present invention.

In the second example embodiment, in an IDT electrode 11A, the center-to-center distance p of a portion is different from the center-to-center distance p of the other portions. In this manner, frequencies at which the unnecessary waves are excited can be effectively dispersed. In this case, for example, d/p≤about 0.5 may be established in any portion of the IDT electrode 11A.

In the IDT electrode 11A, the center-to-center distance p of a plurality of portions may be different from the center-to-center distance p of the other portions. For example, in the IDT electrode 11A, the plurality of portions having mutually different center-to-center distances p may be alternately aligned in the electrode finger orthogonal direction.

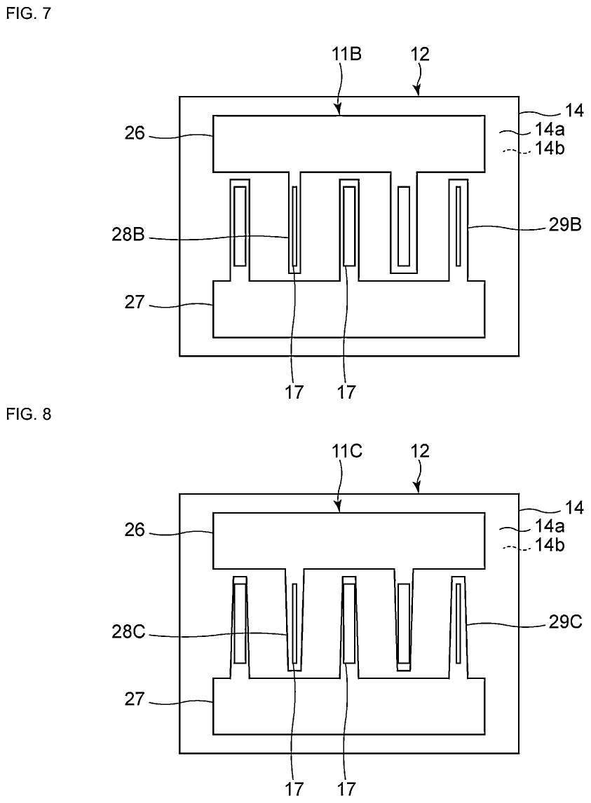

FIG. 7 is a schematic plan view of an acoustic wave device according to a third example embodiment of the present invention.

In the third example embodiment, the line widths of the plurality of electrode fingers are different from each other in the IDT electrode 11B. More specifically, the line width of a first electrode finger 28B and the line width of a second electrode finger 29B are different from each other. The line widths are also different from each other in the plurality of first electrode fingers 28B. On the other hand, the line widths of the plurality of second electrode fingers 29B are the same or substantially the same as each other. The line widths of the plurality of first electrode fingers 28B may be the same or substantially the same as each other. Alternatively, the line widths may be different from each other in the plurality of second electrode fingers 29B.

The line width of at least one electrode finger in the IDT electrode 11B may be different from the line width of the other electrode fingers. In this manner, frequencies at which the unnecessary waves are excited can be effectively dispersed.

FIG. 8 is a schematic plan view of an acoustic wave device according to a fourth example embodiment of the present invention.

In the fourth example embodiment, the line width of each electrode finger of an IDT electrode 11C is not constant. Specifically, the line width of each electrode finger is changed from the base end portion side to the tip portion side. More specifically, the line widths of all of the first electrode fingers 28C and all of the second electrode fingers 29C are changed to become narrower from the base end portion side to the tip portion side.

An aspect of the change in the line width of the electrode finger is not limited to the above-described example. The line width of the electrode finger may be changed to become wider from the base end portion side to the tip portion side. Alternatively, the electrode finger may include both a portion where the line width is changed to become narrower from the base end portion side to the tip portion side and a portion where the line width is changed to become wider from the base end portion side to the tip portion side.

The line width of at least one electrode finger of the IDT electrode 11C may be changed from the base end portion side to the tip portion side. In this manner, frequencies at which the unnecessary waves are excited can be effectively dispersed.

The configurations of the second to fourth example embodiments can also be applied to the configurations of other example embodiments of the present invention. For example, the IDT electrode may have a configuration according to at least one of the second to fourth example embodiments.

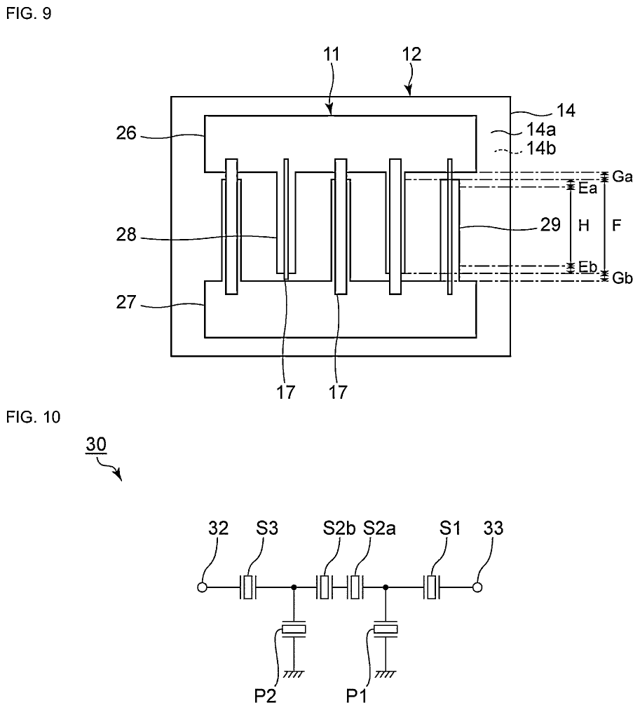

FIG. 9 is a schematic plan view of an acoustic wave device according to a fifth example embodiment of the present invention.

In the present example embodiment, a position where each mass addition film 17 is provided is different from that in the first example embodiment. The acoustic wave device of the present example embodiment has the same or substantially the same configurations as that of the acoustic wave device 10 of the first example embodiment, except for the above-described point.

More specifically, in a plan view, each mass addition film 17 overlaps at least one of the regions where the pair of busbars are provided, both of the gap regions, and the cross region F.

More specifically, the mass addition film 17 provided on the first electrode finger 28 extends from an upper portion of the first electrode finger 28 to an upper portion of the first busbar 26. The mass addition film 17 provided on the first electrode finger 28 also extends from the first electrode finger 28 to the upper portion of the piezoelectric layer 14. A portion of the mass addition film 17 which is directly provided on the piezoelectric layer 14 overlaps the second gap region Gb in a plan view.

Furthermore, at least one mass addition film 17 in the plurality of mass addition films 17 provided on the plurality of first electrode fingers 28 extends from an upper portion of the piezoelectric layer 14 to an upper portion of the second busbar 27. The other at least one mass addition film 17 does not extend to the upper portion of the second busbar 27.

The mass addition film 17 provided on the second electrode finger 29 extends from the upper portion of the second electrode finger 29 to the upper portion of the second busbar 27. The mass addition film 17 provided on the second electrode finger 29 also extends from the second electrode finger 29 to the upper portion of the piezoelectric layer 14. A portion of the mass addition film 17 which is directly provided on the piezoelectric layer 14 overlaps the first gap region Ga in a plan view. Furthermore, the mass addition film 17 provided on the second electrode finger 29 extends from the upper portion of the piezoelectric layer 14 to the upper portion of the first busbar 26. At least one mass addition film 17 in the plurality of mass addition films 17 provided on the plurality of second electrode fingers 29 does not need to extend from the upper portion of the piezoelectric layer 14 to the upper portion of the first busbar 26.

The plurality of mass addition films 17 do not overlap the region in which the busbar is provided in a plan view, and may overlap at least one gap region in of the pair of gap regions.

In the present example embodiment, as in the first example embodiment, the width of at least one mass addition film 17 is different from the widths of the other mass addition films 17. In this manner, the unnecessary waves can be reduced or prevented.

The acoustic wave device according to example embodiments of the present invention can be used for a filter device, for example. This example will be described with reference to a sixth example embodiment of the present invention.

FIG. 10 is a circuit diagram of the filter device according to the sixth example embodiment of the present invention.

A filter device 30 is, for example, a ladder filter. The filter device 30 includes a first signal terminal 32, a second signal terminal 33, a plurality of series arm resonators, and a plurality of parallel arm resonators. In the present example embodiment, all of the series arm resonators and all of the parallel arm resonators are acoustic wave resonators.

For example, the first signal terminal 32 and the second signal terminal 33 may be configured as electrode pads, or may be configured as wirings. In the present example embodiment, the first signal terminal 32 is an antenna terminal. The antenna terminal is connected to an antenna.

Specifically, the plurality of series arm resonators of the filter device 30 include a series arm resonator S1, a series arm resonator S2a, a series arm resonator S2b, and a series arm resonator S3. Specifically, the plurality of parallel arm resonators include a parallel arm resonator P1 and a parallel arm resonator P2.

The series arm resonator S1, the series arm resonator S2a, the series arm resonator S2b, and the series arm resonator S3 are connected in series to each other between the first signal terminal 32 and the second signal terminal 33. The series arm resonator S2a and the series arm resonator S2b are divided acoustic wave resonators. More specifically, the series arm resonator S2a and the series arm resonator S2b are acoustic wave resonators divided in series.

The parallel arm resonator P1 is connected between a connection point of the series arm resonator S1 and the series arm resonator S2a, and a ground potential. The parallel arm resonator P2 is connected between a connection point of the series arm resonator S2b and the series arm resonator S3, and the ground potential. A circuit configuration of the filter device 30 is not limited to the above-described example.

In the present example embodiment, the series arm resonator S2a which is one acoustic wave resonator in the divided acoustic wave resonators is an acoustic wave device according to an example embodiment of the present invention. The series arm resonator S2b which is the other acoustic wave resonator in the divided acoustic wave resonators does not include a mass addition film according to an example embodiment of the present invention. In the series arm resonator S2a, the unnecessary waves can be reduced or prevented. Therefore, deterioration in filter characteristics in the filter device 30 can be reduced or prevented. In addition, the series arm resonator S2b included in the plurality of divided acoustic wave resonators does not include the mass addition film. In this manner, an increase in an insertion loss in the filter device 30 can be reduced or prevented.

The filter device 30 may include a plurality of the divided acoustic wave resonators. The plurality of divided acoustic wave resonators may be a plurality of series arm resonators divided in series, or may be a plurality of series arm resonators divided in parallel. Alternatively, the plurality of divided acoustic wave resonators may be a plurality of parallel arm resonators divided in series, or may be a plurality of parallel arm resonators divided in parallel.

For example, the plurality of divided acoustic wave resonators may be a plurality of acoustic wave resonators divided in series or divided in parallel into three or more. At least one of the plurality of divided acoustic wave resonators may be an acoustic wave device according to an example embodiment of the present invention. The other at least one of the plurality of divided acoustic wave resonators does not need to include the mass addition film. In this manner, in the filter device 30, an increase in the insertion loss can be reduced or prevented, and deterioration in filter characteristics can be reduced or prevented.

At least one acoustic wave resonator in the filter device 30 may be an acoustic wave device according to an example embodiment of the present invention. For example, at least one of the acoustic wave resonators other than the divided acoustic wave resonator may be an acoustic wave device according to an example embodiment of the present invention. In this case as well, the unnecessary waves can be reduced or prevented in the acoustic wave resonator which is the acoustic wave device according to the present invention. Therefore, deterioration in filter characteristics in the filter device 30 can be reduced or prevented.

Hereinafter, details of the thickness shear mode will be described. The “electrode” in the IDT electrode (to be described later) corresponds to the electrode finger. The support in the following example corresponds to the support substrate.

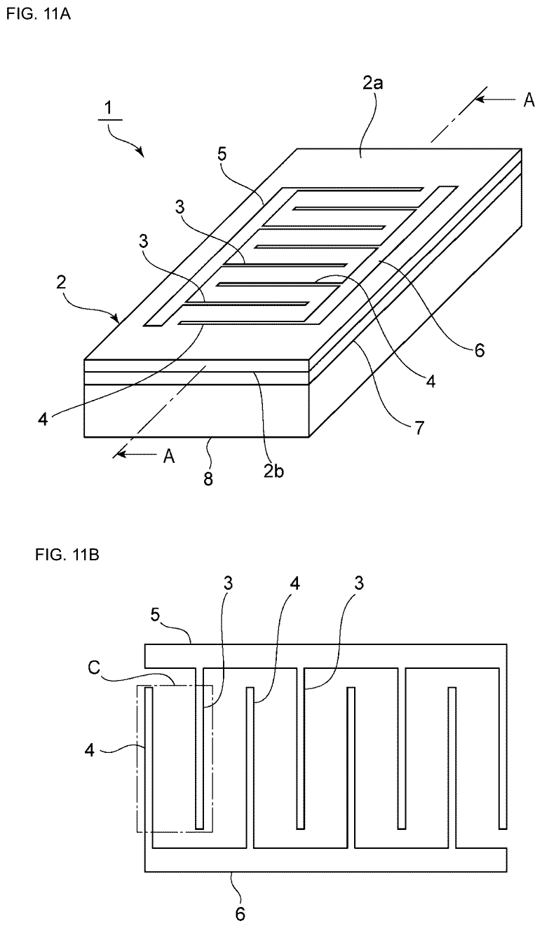

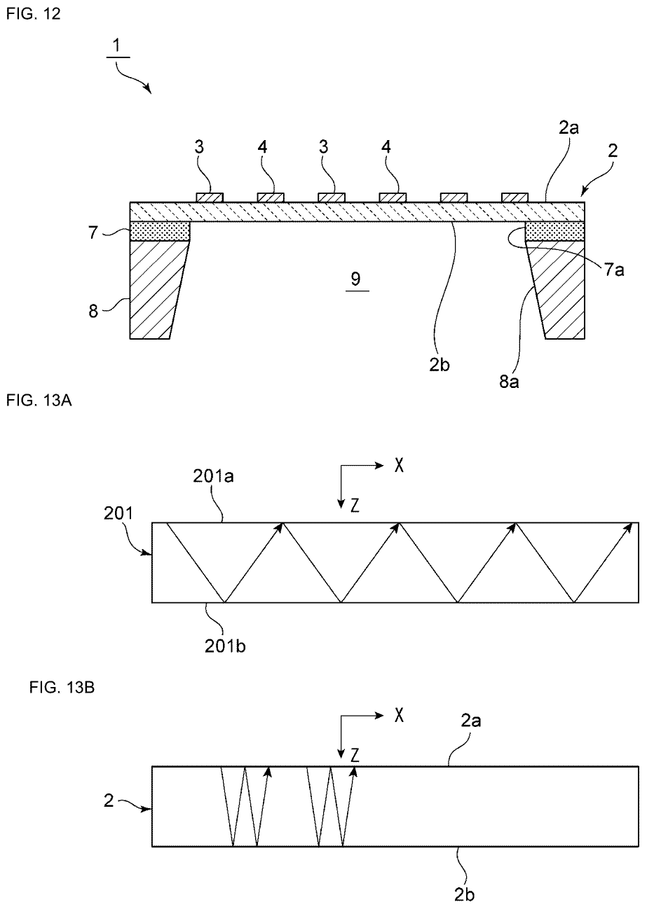

FIG. 11A is a schematic perspective view showing an appearance of the acoustic wave device using the bulk wave in the thickness shear mode, FIG. 11B is a plan view showing an electrode structure on the piezoelectric layer, and FIG. 12 is a cross-sectional view of a portion taken along line A-A in FIG. 11A.

The acoustic wave device 1 includes a piezoelectric layer 2 made of LiNbO₃, for example. The piezoelectric layer 2 may be formed of LiTaO₃, for example. Cut-angles of LiNbO₃ or LiTaO₃ are Z-cut, but may be a rotated Y-cut or X-cut. The thickness of the piezoelectric layer 2 is not particularly limited, but is, for example, preferably about 40 nm or larger and about 1000 nm or smaller, and more preferably about 50 nm or larger and about 1000 nm or smaller in order to effectively excite the thickness shear mode. The piezoelectric layer 2 includes first and second main surfaces 2a and 2b facing each other. Electrodes 3 and 4 are provided on the first main surface 2a. Here, the electrode 3 is an example of a “first electrode”, and the electrode 4 is an example of a “second electrode”. In FIGS. 11A and 11B, the plurality of electrodes 3 are a plurality of first electrode fingers connected to a first busbar 5. The plurality of electrodes 4 are a plurality of second electrode fingers connected to a second busbar 6. The plurality of electrodes 3 and the plurality of electrodes 4 are interdigitated with each other. The electrode 3 and the electrode 4 have a rectangular or substantially rectangular shape, and have a length direction. The electrode 3 and the electrode 4 adjacent thereto face each other in a direction orthogonal or substantially orthogonal to the length direction. Both the length direction of the electrodes 3 and 4 and the direction orthogonal or substantially orthogonal to the length direction of the electrodes 3 and 4 are directions intersecting the thickness direction of the piezoelectric layer 2. Therefore, the electrode 3 and the electrode 4 adjacent thereto face each other in the direction intersecting the thickness direction of the piezoelectric layer 2. In addition, the length direction of the electrodes 3 and 4 may be replaced with the direction orthogonal or substantially orthogonal to the length direction of the electrodes 3 and 4 shown in FIGS. 11A and 11B. That is, in FIGS. 11A and 11B, the electrodes 3 and 4 may extend in the extending direction of the first busbar 5 and the second busbar 6. In this case, the first busbar 5 and the second busbar 6 extend in the extending direction of the electrodes 3 and 4 in FIGS. 11A and 11B. A plurality of pairs of structures in which the electrode 3 connected to one potential and the electrode 4 connected to the other potential are adjacent to each other are provided in the direction orthogonal to the length direction of the electrodes 3 and 4. Here, a case where the electrodes 3 and 4 are adjacent to each other does not mean a case where the electrodes 3 and 4 are disposed to be in direct contact with each other, but means a case where the electrodes 3 and 4 are disposed with a space interposed therebetween. In addition, when the electrodes 3 and 4 are adjacent to each other, the electrode connected to a hot electrode or a ground electrode, including the other electrodes 3 and 4, is not disposed between the electrodes 3 and 4. The number of pairs does not need to be integer pairs, but may be 1.5 pairs, 2.5 pairs, or the like. The center-to-center distance, that is, a pitch between the electrodes 3 and 4 is, for example, preferably in a range of about 1 μm or larger and about 10 μm or smaller. In addition, the widths of the electrodes 3 and 4, that is, the dimensions of the electrodes 3 and 4 in the facing direction are, for example, preferably in a range of about 50 nm or larger and about 1,000 nm or smaller, and more preferably in a range of about 150 nm or larger and about 1,000 nm or smaller. The center-to-center distance between the electrodes 3 and 4 is a distance connecting the center of the dimension (width dimension) of the electrode 3 in the direction orthogonal or substantially orthogonal to the length direction of the electrode 3 and the center of the dimension (width dimension) of the electrode 4 in the direction orthogonal or substantially orthogonal to the length direction of the electrode 4.

In the acoustic wave device 1, since the Z-cut piezoelectric layer is used, the direction orthogonal or substantially orthogonal to the length direction of the electrodes 3 and 4 is a direction orthogonal or substantially orthogonal to a polarization direction of the piezoelectric layer 2. When piezoelectric materials with different cut-angles are used as the piezoelectric layer 2, the configuration is not limited to this example. Here, description of “orthogonal” is not limited to being strictly orthogonal, but may be substantially orthogonal (angle formed between the direction orthogonal to the length direction of the electrodes 3 and 4 and the polarization direction falls within a range of 90°±10°, for example).

A support 8 is laminated on the second main surface 2b side of the piezoelectric layer 2 with an insulating layer 7 interposed therebetween. The insulating layer 7 and the support 8 have a frame shape, and include through holes 7a and 8a as shown in FIG. 12. In this manner, a cavity portion 9 is provided. The cavity portion 9 is provided not to disturb the vibration of the excitation region C of the piezoelectric layer 2. Therefore, the support 8 is laminated on the second main surface 2b with the insulating layer 7 interposed therebetween at a position not overlapping the portion where at least the pair of electrodes 3 and 4 are provided. The insulating layer 7 does not have to be provided. Therefore, the support 8 can be directly or indirectly laminated on the second main surface 2b of the piezoelectric layer 2.

The insulating layer 7 is made of silicon oxide, for example. In addition to silicon oxide, an appropriate insulating material such as, for example, silicon oxynitride or alumina can be used. The support 8 is made of Si, for example. A plane orientation of a surface of Si on the piezoelectric layer 2 side may be (100), (110), or (111). It is preferable that Si of the support 8 has high resistance having, for example, resistivity of about 4 kΩcm or higher. The support 8 can also be made of an appropriate insulating material or semiconductor material.

Examples of the material of the support 8 include piezoelectric materials such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrodes 3 and 4 and the first and second busbars 5 and 6 are made of appropriate metal or alloys such as Al and AlCu alloys, for example. In the acoustic wave device 1, for example, the electrodes 3 and 4 and the first and second busbars 5 and 6 have a structure in which Al films are laminated on a Ti film. A close contact layer other than the Ti film may be used, for example.

During driving, an AC voltage is applied between the plurality of electrodes 3 and the plurality of electrodes 4. More specifically, the AC voltage is applied between the first busbar 5 and the second busbar 6. In this manner, it is possible to obtain the resonance characteristics using the bulk wave in the thickness shear mode excited in the piezoelectric layer 2. In the acoustic wave device 1, when the thickness of the piezoelectric layer 2 is defined as d and the center-to-center distance between any adjacent electrodes 3 and 4 in the plurality of pairs of electrodes 3 and 4 is defined as p, d/p is about 0.5 or smaller, for example. In this manner, the bulk wave in the thickness shear mode is effectively excited, and satisfactory resonance characteristics can be obtained. More preferably, for example, d/p is about 0.24 or smaller, and in this case, more satisfactory resonance characteristics can be obtained.

In the acoustic wave device 1, since the above-described configuration is provided, even when the number of pairs of the electrodes 3 and 4 is reduced to reduce the size, a Q value is less likely to be decreased. The reason is that a propagation loss is small even when the number of electrode fingers in reflectors on both sides is reduced. In addition, the number of electrode fingers can be reduced by using the bulk wave in the thickness shear mode. A difference between a Lamb wave used for the acoustic wave device and the bulk wave in the thickness shear mode will be described with reference to FIGS. 13A and 13B.

FIG. 13A is a schematic elevational cross-sectional view showing the Lamb wave that propagates through the piezoelectric film of the acoustic wave device as described in Japanese Unexamined Patent Application Publication No. 2012-257019. Here, the wave propagates through a piezoelectric film 201 as indicated by an arrow. Here, in the piezoelectric film 201, a first main surface 201a and a second main surface 201b face each other, and the thickness direction connecting the first main surface 201a and the second main surface 201b is a Z-direction. An X-direction is a direction in which the electrode fingers of the IDT electrodes are aligned. As shown in FIG. 13A, in the Lamb wave, the wave propagates in the X-direction as shown in the drawing. Since the wave is a plate wave, the piezoelectric film 201 vibrates as a whole. Since the wave propagates in the X-direction, the reflectors are disposed on both sides to obtain the resonance characteristics. Therefore, the propagation loss of the wave occurs, and the Q value is decreased when the size is reduced, that is, when the number of pairs of the electrode fingers is reduced.

In contrast, as shown in FIG. 13B, in the acoustic wave device 1, since vibration displacement occurs in a thickness shear direction, the waves mostly propagate and resonate in the direction connecting the first main surface 2a and the second main surface 2b of the piezoelectric layer 2, that is, the Z-direction. That is, an X-direction component of the wave is significantly smaller than a Z-direction component. In addition, since the resonance characteristics are obtained by the propagation of the wave in the Z-direction, the propagation loss is less likely to occur even when the number of the electrode fingers of the reflector is reduced. Furthermore, even when the number of pairs of the electrode pairs including the electrodes 3 and 4 is reduced to reduce the size, the Q value is less likely to be decreased.

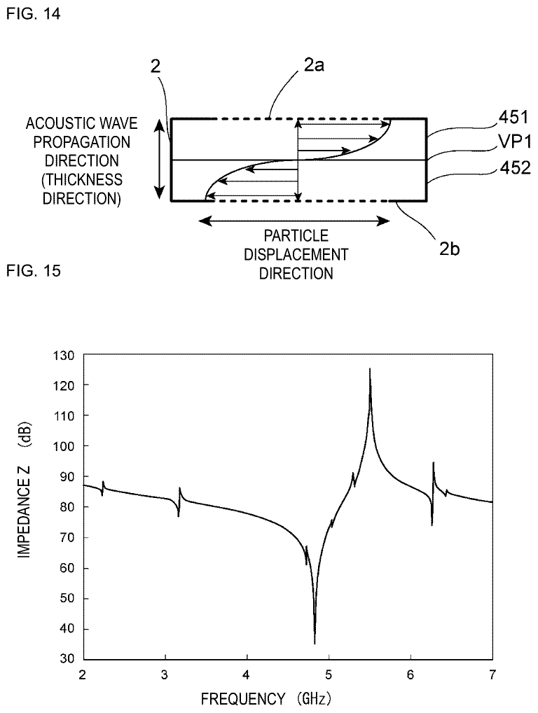

As shown in FIG. 14, amplitude directions of the bulk waves in the thickness shear mode are opposite to each other between a first region 451 included in the excitation region C of the piezoelectric layer 2 and a second region 452 included in the excitation region C. FIG. 14 schematically shows the bulk waves when a voltage in which the electrode 4 has a higher potential than the electrode 3 is applied between the electrodes 3 and 4. The first region 451 is a region of the excitation region C between a virtual plane VP1 orthogonal to the thickness direction of the piezoelectric layer 2 and bisecting the piezoelectric layer 2, and the first main surface 2a. The second region 452 is a region of the excitation region C between the virtual plane VP1 and the second main surface 2b.

As described above, in the acoustic wave device 1, although at least the pair of electrodes including the electrodes 3 and 4 are provided, the waves do not propagate in the X-direction. Therefore, the number of pairs of the electrode pair including the electrodes 3 and 4 does not need to be the plurality of pairs. That is, at least the pair of electrodes may be provided.

For example, the electrode 3 is connected to the hot potential, and the electrode 4 is connected to the ground potential. The electrode 3 may be connected to the ground potential, and the electrode 4 may be connected to the hot potential. In the acoustic wave device 1, as described above, at least the pair of electrodes is the electrodes connected to the hot potential or the electrodes connected to the ground potential, and a floating electrode is not provided.

FIG. 15 is a view showing the resonance characteristics of the acoustic wave device shown in FIG. 12. Design parameters of the acoustic wave device 1 having the resonance characteristics are as follows.

Piezoelectric layer 2: LiNbO₃ with Euler angles (0°, 0°, and 90°), thickness=about 400 nm.

When viewed in the direction orthogonal or substantially orthogonal to the length direction of the electrodes 3 and 4, the length of the region in which the electrodes 3 and 4 overlap each other, that is, the length of the excitation region C=about 40 μm, the number of pairs of the electrodes including the electrodes 3 and 4=21 pairs, the center distance between the electrodes=about 3 μm, the width of the electrodes 3 and 4=about 500 nm, and d/p=about 0.133.

Insulating layer 7: silicon oxide film having the thickness of about 1 μm.

### Support 8: Si.

The length of the excitation region C is the dimension along the length direction of the electrodes 3 and 4 of the excitation region C.

In the acoustic wave device 1, an electrode-to-electrode distance of the electrode pair including the electrodes 3 and 4 is set to be equal or substantially equal in all of the plurality of pairs. That is, the electrodes 3 and 4 are disposed at an equal or substantially equal pitch.

As is clear from FIG. 15, satisfactory resonance characteristics with the fractional bandwidth of about 12.5% are obtained regardless of the presence of the reflector.

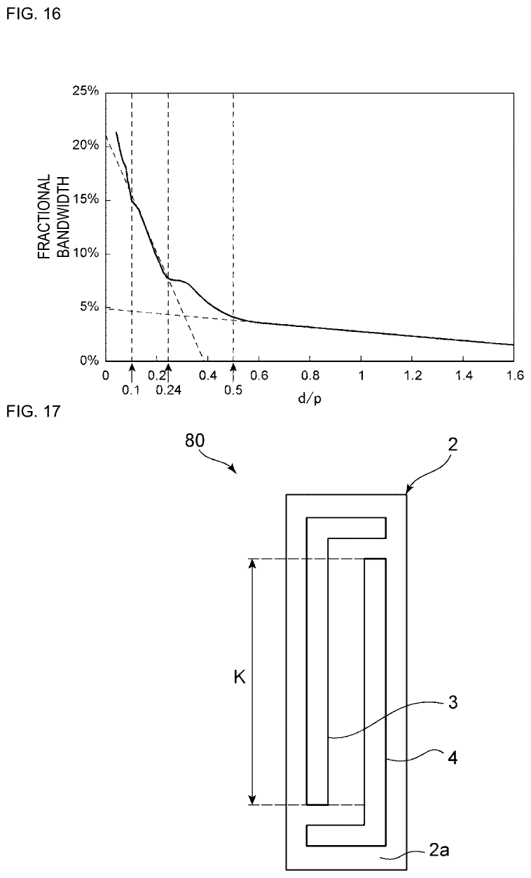

When the thickness of the piezoelectric layer 2 is defined as d and the center-to-center distance of the electrodes 3 and 4 is defined as p, in the acoustic wave device 1, for example, as described above, d/p is about 0.5 or smaller, and is more preferably about 0.24 or smaller. This configuration will be described with reference to FIG. 16.

The plurality of acoustic wave devices are obtained by changing d/p as in the acoustic wave device that obtains the resonance characteristics shown in FIG. 15. FIG. 16 is a view showing a relationship between d/p and a fractional bandwidth as the resonator of the acoustic wave device.

As is clear from FIG. 16, when d/p>about 0.5, the fractional bandwidth is smaller than about 5% even when d/p is adjusted. In contrast, in a case of d/p 5 about 0.5, when d/p is changed within this range, the fractional bandwidth can be about 5% or larger, that is, a resonator having a high coupling coefficient can be provided. In addition, when d/p is about 0.24 or smaller, the fractional bandwidth can be increased to about 7% or larger. In addition, when d/p is adjusted within this range, a resonator having a wider fractional bandwidth can be obtained, and a resonator having a higher coupling coefficient can be realized. Therefore, for example, it can be understood that the resonator using the bulk wave in the thickness shear mode and having the high coupling coefficient can be provided by adjusting d/p to about 0.5 or smaller.

FIG. 17 is a plan view of the acoustic wave device using the bulk wave in the thickness shear mode. In an acoustic wave device 80, the pair of electrodes including the electrode 3 and electrode 4 is provided on the first main surface 2a of the piezoelectric layer 2. K in FIG. 17 is a cross width. As described above, in an acoustic wave device according to an example embodiment of the present invention, the number of pairs of the electrodes may be one pair. Even in this case, when d/p is about 0.5 or smaller, the bulk wave in the thickness shear mode can be effectively excited.

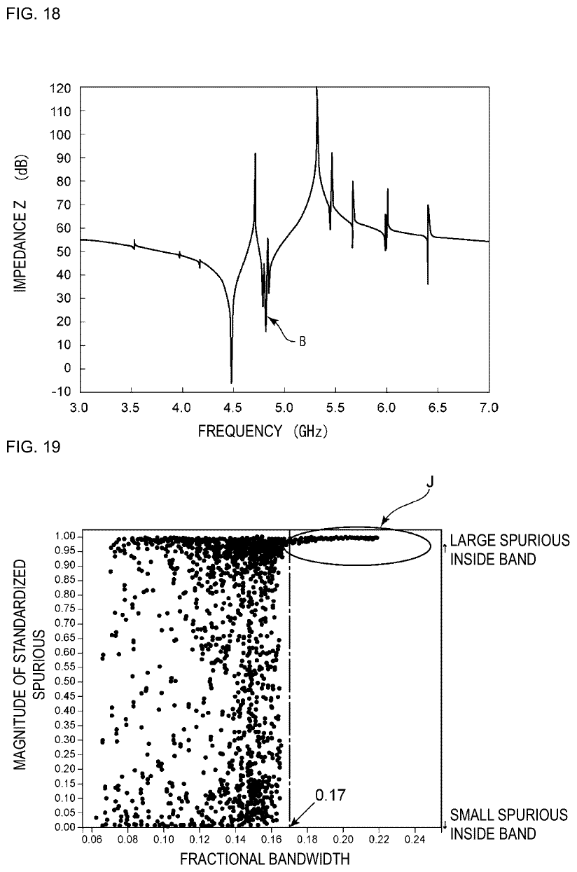

In the acoustic wave device 1, preferably, a metallization ratio MR of any adjacent electrodes 3 and 4 in the plurality of electrodes 3 and 4 to the excitation region C which is the region in which the adjacent electrodes 3 and 4 overlap each other when viewed in the facing direction satisfies MR≤about 1.75(d/p)+0.075, for example. In this case, the spurious waves can be effectively reduced. This configuration will be described with reference to FIGS. 18 and 19. FIG. 18 is a reference view showing an example of the resonance characteristics of the acoustic wave device 1. For example, the spurious wave indicated by an arrow B appears between the resonant frequency and the anti-resonant frequency. In the example, as d/p=about 0.08, the Euler angles (0°, 0°, and 90°) of LiNbO₃ are set. In addition, the metallization ratio MR=about 0.35 is set.

The metallization ratio MR will be described with reference to FIG. 11B. In the electrode structure of FIG. 11B, in a case of focusing on the pair of electrodes 3 and 4, only the pair of electrodes 3 and 4 are provided. In this case, a portion surrounded by the one-dot chain line is the excitation region C. The excitation region C is a region that overlaps the electrode 4 in the electrode 3 when the electrode 3 and the electrode 4 are viewed in the direction orthogonal or substantially orthogonal to the length direction of the electrodes 3 and 4, that is, in the facing direction, a region that overlaps the electrode 3 in the electrode 4, and a region in which the electrode 3 and the electrode 4 overlap each other in the region between the electrode 3 and the electrode 4. An area of the electrodes 3 and 4 inside the excitation region C with respect to an area of the excitation region C is the metallization ratio MR. That is, the metallization ratio MR is a ratio of an area of the metallization portion with respect to an area of the excitation region C.

When the plurality of pairs of electrodes are provided, a ratio of the metallization portion included in the entire excitation region with respect to a total area of the excitation region may be MR.

FIG. 19 is a view showing a relationship between the fractional bandwidth and a phase rotation amount of the impedance of the spurious wave standardized at about 180 degrees as a magnitude of the spurious when a large number of acoustic wave resonators are configured according to a form of the acoustic wave device 1. The fractional bandwidth is adjusted by changing the film thickness of the piezoelectric layer and the dimensions of the electrodes. In addition, for example, FIG. 19 shows results when the piezoelectric layer made of Z-cut LiNbO₃ is used, but shows the same tendency even when the piezoelectric layer having other cut-angles is used.

In a region surrounded by an ellipse J in FIG. 19, the spurious wave is as large as about 1.0. As is clear from FIG. 19, when the fractional bandwidth exceeds about 0.17, that is, exceeds about 17%, a large spurious wave with a spurious level of about 1 or larger appears inside a pass band even when parameters forming the fractional bandwidth are changed. That is, as in the resonance characteristics shown in FIG. 18, a large spurious wave indicated by an arrow B appears inside the band. Therefore, the fractional bandwidth is, for example, preferably about 17% or smaller. In this case, the spurious wave can be reduced by adjusting the film thickness of the piezoelectric layer 2 and the dimensions of the electrodes 3 and 4.

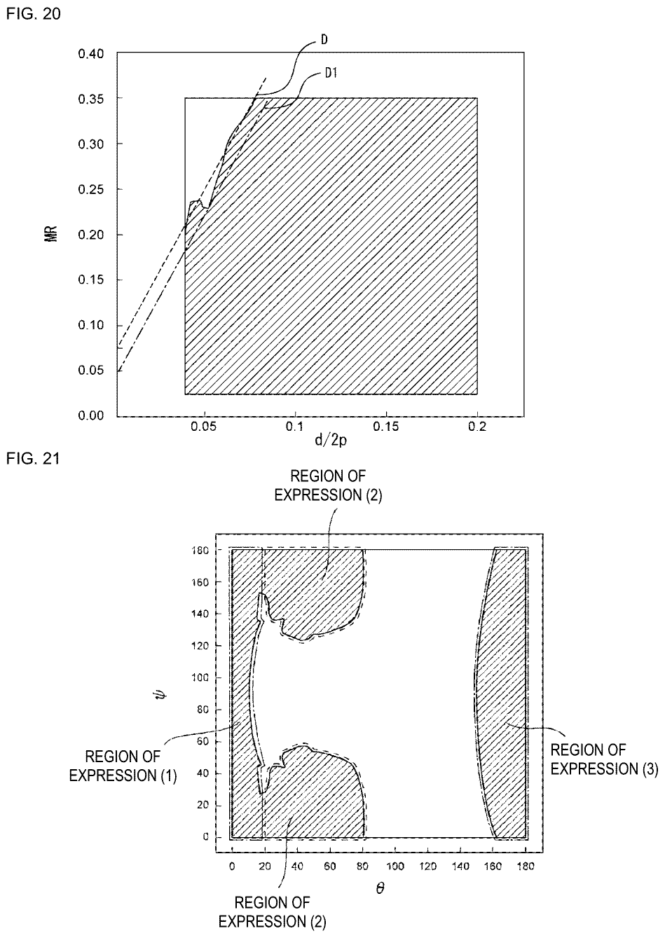

FIG. 20 is a view showing a relationship between d/2p, the metallization ratio MR, and the fractional bandwidth. In the acoustic wave device described above, various acoustic wave devices having different d/2p and MR are configured, and the fractional bandwidth is measured. A hatched portion on a right side of a broken line D in FIG. 20 is a region in which the fractional bandwidth is about 17% or smaller. A boundary between the hatched region and a non-hatched region is expressed by MR=about 3.5(d/2p)+0.075. That is, MR=about 1.75(d/p)+0.075. Therefore, for example, preferably, MR about 1.75(d/p)+0.075. In this case, it is easy to set the fractional bandwidth to about 17% or smaller. It is more preferable, for example, to set a region on a right side of MR=about 3.5(d/2p)+0.05 indicated by a one-dot chain line D1 in FIG. 20. That is, in a case of MR≤about 1.75(d/p)+0.05, the fractional bandwidth can be reliably set to about 17% or smaller.

FIG. 21 is a view showing a map of the fractional bandwidth with respect to Euler angles (0°, θ, and ψ) of LiNbO₃ when d/p is infinitely close to 0. A hatched portion in FIG. 21 is a region in which the fractional bandwidth of at least about 5% or larger is obtained, and when a range of the region is approximated, the range is expressed by Expression (1), Expression (2), and Expression (3).

$$( 0 ° \pm 10 ° , 0 ° to 20 ° , any ψ ) \qquad Expression ( l )$$

$$( 0 ° \pm 10 ° , 20 ° to 80 ° , 0 ° to 60 ° {( 1 - {( θ - 50 )}^{2} / 900 )}^{1 / 2} ) \text{} or \qquad Expression ( 2 )$$

$$( 0 ° \pm 10 ° , 20 ° to 80 ° , [ 180 ° - 60 ° {( 1 - {( θ - 50 )}^{2} / 900 )}^{1 / 2} ] to 180 ° )$$

$$( 0 ° \pm 10 ° , [ 180 ° - 30 ° {( 1 - {( ψ - 90 )}^{2} / 8100 )}^{1 / 2} ] 180 ° , \qquad Expression ( 3 )$$

$$any ψ )$$

Therefore, in a case of the Euler angle range of Expression (1), Expression (2), or Expression (3), it is preferable since the fractional bandwidth can be sufficiently widened. The same applies to a case where the piezoelectric layer 2 is the lithium tantalate layer.

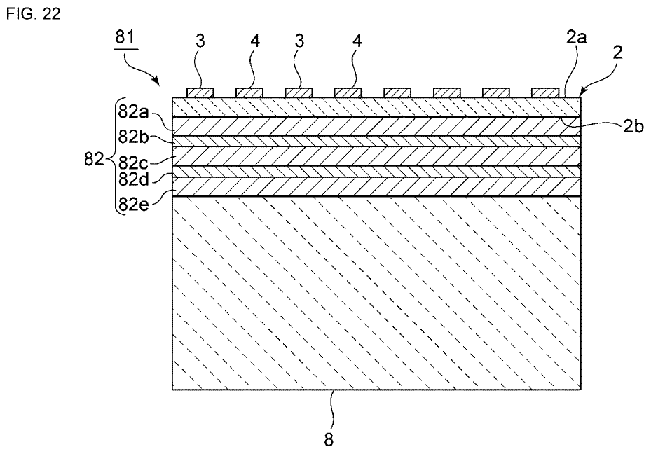

FIG. 22 is an elevational cross-sectional view of an acoustic wave device including an acoustic multilayer film.

In an acoustic wave device 81, an acoustic multilayer film 82 is laminated on the second main surface 2b of the piezoelectric layer 2. The acoustic multilayer film 82 has a multilayer structure including low acoustic impedance layers 82a, 82c, and 82e having a relatively low acoustic impedance and high acoustic impedance layers 82b and 82d having a relatively high acoustic impedance. When the acoustic multilayer film 82 is used, the bulk wave in the thickness shear mode can be confined in the piezoelectric layer 2 without using the cavity portion 9 in the acoustic wave device 1. In the acoustic wave device 81, the resonance characteristics based on the bulk wave in the thickness shear mode can be obtained by setting d/p to about 0.5 or smaller, for example. In the acoustic multilayer film 82, the number of laminated layers of the low acoustic impedance layers 82a, 82c, and 82e and the high acoustic impedance layers 82b and 82d is not particularly limited. At least one layer of the high acoustic impedance layers 82b and 82d may be disposed on a side farther from the piezoelectric layer 2 than the low acoustic impedance layers 82a, 82c, and 82e.

The low acoustic impedance layers 82a, 82c, and 82e and the high acoustic impedance layers 82b and 82d can be made of an appropriate material as long as the above-described relationship of the acoustic impedance is satisfied. Examples of the materials of the low acoustic impedance layers 82a, 82c, and 82e include silicon oxide, silicon oxynitride, and the like. In addition, examples of the materials of the high acoustic impedance layers 82b and 82d include alumina, silicon nitride, metal, and the like.

In the acoustic wave devices according to the first to fifth example embodiments, for example, the acoustic multilayer film 82 shown in FIG. 22 may be provided as the acoustic reflection film between the support and the piezoelectric layer. Specifically, the support and the piezoelectric layer may be disposed such that at least a portion of the support and at least a portion of the piezoelectric layer face each other across the acoustic multilayer film 82. In this case, in the acoustic multilayer film 82, the low acoustic impedance layer and the high acoustic impedance layer may be alternately laminated. The acoustic multilayer film 82 may be the acoustic reflection portion in the acoustic wave device.

In the acoustic wave devices according to the first to fifth example embodiments using the bulk wave in the thickness shear mode, as described above for example, d/p is preferably about 0.5 or smaller, and more preferably about 0.24 or smaller. In this manner, more satisfactory resonance characteristics can be obtained. Furthermore, in the excitation regions in the acoustic wave devices according to the first to fifth example embodiments using the bulk wave in the thickness shear mode, for example, as described above, it is preferable that MR≤1.75 (d/p)+about 0.075 is satisfied. In this case, the spurious wave can be more reliably reduced or prevented.

It is preferable that the piezoelectric layers in the acoustic wave devices according to the first to fifth example embodiments using the bulk wave in the thickness shear mode are the lithium niobate layer or the lithium tantalate layer, for example. In addition, it is preferable that the Euler angles (φ, θ, ψ) of lithium niobate or lithium tantalate forming the piezoelectric layer fall within the range of Expression (1), Expression (2), or Expression (3). In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a support substrate;
a piezoelectric layer on the support;
an interdigital transducer (IDT) electrode on the piezoelectric layer and including a pair of busbars facing each other and a plurality of electrode fingers; and
a plurality of mass addition films on the plurality of electrode fingers; wherein
in a plan view along a lamination direction of the support and the piezoelectric layer, an acoustic reflection portion is provided at a position overlapping with at least a portion of the IDT electrode in the support;
when a thickness of the piezoelectric layer is defined as d and a center-to-center distance between adjacent electrode fingers of the plurality of electrode fingers is defined as p, d/p is about 0.5 or smaller;
when viewed in an electrode finger orthogonal direction orthogonal or substantially orthogonal to an electrode finger extending direction in which the plurality of electrode fingers extend, a region in which the adjacent electrode fingers overlap each other is a cross region;
the cross region includes a central region, and a first edge region and a second edge region facing each other across the central region in the electrode finger extending direction;
at least a portion of the plurality of mass addition films each overlaps the central region in a plan view; and
when a dimension of the plurality of mass addition films along the electrode finger orthogonal direction is defined as a width of the plurality of mass addition films, a width of at least one of the plurality of mass addition films is different from a width of other ones of the plurality of mass addition films.

2. The acoustic wave device according to claim 1, wherein
the plurality of mass addition films include mass addition films respectively provided on the adjacent electrode fingers; and
the widths of the mass addition films provided on the adjacent electrode fingers are different from each other.

3. The acoustic wave device according to claim 1, wherein the plurality of mass addition films include a dielectric.

4. The acoustic wave device according to claim 3, wherein the plurality of mass addition films include silicon oxide.

5. The acoustic wave device according to claim 3, wherein a density of the plurality of mass addition films is higher than a density of silicon oxide.

6. The acoustic wave device according to claim 1, wherein the plurality of mass addition films include metal.

7. The acoustic wave device according to claim 1, wherein, in the IDT electrode, the center-to-center distance p of at least a portion is different from the center-to-center distance p of other portions.

8. The acoustic wave device according to claim 1, wherein, when a dimension of the electrode finger along the electrode finger orthogonal direction is defined as a line width of the electrode finger, the line width of at least one of the plurality of electrode fingers is different from the line width of other ones of the plurality of electrode fingers.

9. The acoustic wave device according to claim 1, wherein
each of the plurality of electrode fingers includes a base end portion connected to one of the pair of busbars and a tip portion facing the base end portion; and
when a dimension of the electrode finger along the electrode finger orthogonal direction is defined as a line width of the electrode finger, the line width of at least one of the plurality of electrode fingers is changed from a side of the base end portion to a side of the tip portion.

10. The acoustic wave device according to claim 1, wherein d/p is about 0.24 or smaller.

11. The acoustic wave device according to claim 1, wherein
when viewed in the electrode finger orthogonal direction, a center-to-center region in the electrode finger orthogonal direction of the adjacent electrode fingers, which is a region in which the adjacent electrode fingers overlap each other, is an excitation region; and
when a metallization ratio of the plurality of electrode fingers with respect to the excitation region is defined as MR, MR≤about 1.75(d/p)+0.075 is satisfied.

12. The acoustic wave device according to claim 1, wherein the piezoelectric layer includes lithium tantalate or lithium niobate.

13. The acoustic wave device according to claim 12, wherein Euler angles (φ, θ, and ψ) of the lithium niobate or the lithium tantalate of the piezoelectric layer fall within a range of Expression (1), Expression (2), or Expression (3):
$$( 0 ° \pm 10 ° , 0 ° to 20 ° , any ψ ) ; \qquad Expression ( l )$$
$$( 0 ° \pm 10 ° , 20 ° to 80 ° , 0 ° to 60 ° {( 1 - {( θ - 50 )}^{2} / 900 )}^{1 / 2} ) or \qquad Expression ( 2 )$$
$$( 0 ° \pm 10 ° , 20 ° to 80 ° , [ 180 ° - 60 ° {( 1 - {( θ - 50 )}^{2} / 900 )}^{1 / 2} ] to 180 ° ) ; and$$
$$( 0 ° \pm 10 ° , [ 180 ° - 30 ° {( 1 - {( ψ - 90 )}^{2} / 8100 )}^{1 / 2} ] 180 ° , \qquad Expression ( 3 )$$
$$any ψ ) .$$

14. The acoustic wave device according to claim 1, wherein the acoustic reflection portion is a cavity portion; and
the support and the piezoelectric layer are positioned such that a portion of the support and a portion of the piezoelectric layer face each other across the cavity portion.

15. The acoustic wave device according to claim 1, wherein
the acoustic reflection portion includes an acoustic reflection film including a high acoustic impedance layer having a relatively high acoustic impedance and a low acoustic impedance layer having a relatively low acoustic impedance; and
the support and the piezoelectric layer are positioned such that at least a portion of the support and at least a portion of the piezoelectric layer face each other across the acoustic reflection film.

16. A filter device comprising:
a plurality of acoustic wave resonators including divided acoustic wave resonators; wherein
at least one of the divided acoustic wave resonators is defined by the acoustic wave device according to claim 1; and
at least another one of the divided acoustic wave resonators is an acoustic wave resonator that does not include the mass addition film of the acoustic wave device.

17. The filter device according to claim 16, wherein
the plurality of mass addition films include mass addition films respectively provided on the adjacent electrode fingers; and
the widths of the mass addition films provided on the adjacent electrode fingers are different from each other.

18. The filter device according to claim 16, wherein the plurality of mass addition films include a dielectric.

19. The filter device according to claim 18, wherein the plurality of mass addition films include silicon oxide.

20. The filter device according to claim 18, wherein a density of the plurality of mass addition films is higher than a density of silicon oxide.
